(19) United States
(12) Patent Application Publication
(10) Pub. No.: US 2021/0262117 A1
(43) Pub. Date: Aug. 26, 2021

(54) PLASMA SHAPING FOR DIAMOND GROWTH

(71) Applicant: J2 Materials, LLC, Morton Grove, IL (US)

(72) Inventors: John P. Ciraldo, Chicago, IL (US); Jonathan Levine-Miles, Chicago, IL (US)

(21) Appl. No.: 17/184,219

(22) Filed: Feb. 24, 2021

Related U.S. Application Data
(60) Provisional application No. 62/980,673, filed on Feb. 24, 2020.

(51) Int. Cl. C30B 25/02; C30B 29/04; C23C 16/511; C23C 16/27

(52) U.S. Cl. CPC C30B 25/02; C23C 16/274; C23C 16/511; C30B 29/04

(57) ABSTRACT

A system grows diamonds. The system includes a chemical vapor deposition reactor having a microwave chamber. The system further includes a single-crystal seed configured to be positioned in the chamber. The system also includes a precursor gas. A microwave source is configured to energize the precursor gas to produce a plasma plume. An electromagnetic source of the system is configured to generate a steering field to adjust a position of the plasma plume in the chamber and/or to adjust a shape of the plasma plume.

### PRIORITY

This patent application claims priority from provisional U.S. patent application No. 62/980,673, filed Feb. 24, 2020, entitled, “PLASMA SHAPING FOR DIAMOND GROWTH,” and naming John Ciraldo and Jonathan Levine-Miles as inventors, the disclosure of which is incorporated herein, in its entirety, by reference.

### FIELD OF THE INVENTION

Illustrative embodiments of the invention generally relate to formation of diamonds on substrates and, more particularly, the illustrative embodiments of the invention relate to plasma shaping for targeted diamond growth.

### BACKGROUND OF THE INVENTION

Diamonds are used in a wide variety of applications. For example, they can be used for producing integrated circuits, or as lenses for laser systems. They also can be used simply as gemstones. Fabricating diamonds, however, can produce a number of technical challenges.

Chemical vapor deposition (CVD) is a process in which films of materials are deposited from the vapor phase by the decomposition of chemicals on the surface of a substrate. Most frequently the process is thermally driven but photo- and plasma-assisted methods are also used. The deposition of the film is controlled by a chemical reaction.

### SUMMARY OF VARIOUS EMBODIMENTS

In accordance with an embodiment of the invention, a system grows diamonds. The system includes a chemical vapor deposition reactor having a microwave chamber. The system further includes a single-crystal seed configured to be positioned in the chamber. The system also includes a precursor gas. A microwave source is configured to energize the precursor gas to produce a plasma plume. An electromagnetic source of the system is configured to generate a steering field to adjust a position of the plasma plume in the chamber and/or to adjust a shape of the plasma plume.

The microwave source emits microwave radiation. The microwave source may produce a first electric field that energizes the gas. The electrically charged gas may include methane and hydrogen. The first electric field and the steering field may be at least partially superposed. The electromagnetic source may include, among other things, a magnetic coil, an electrically charged ring, and/or an electrically biased mechanical support.

The system may further include a mechanical support on which the single-crystal seed is positioned. The system may further include a plurality of single-crystal seeds formed from diamond. Additionally, the system may include a deposition feedback system. The deposition feedback system is configured to determine a temperature of one or more seeds, measure a dimension of one or more grown diamonds, and/or determine a shape of the plasma plume. As a result of the deposition feedback, the field strength and/or other property of one or more electromagnetic sources may be adjusted.

In accordance with another embodiment, a method generates a plasma plume in a chamber. The chamber is configured so that the plasma plume is unstable or metastable. Accordingly, the plasma plume moves between a first position and a second position. The method biases the plasma plume towards the first position.

The method may also provide a single-crystal seed in the chamber. The chamber may be a cylindrical chamber. Carbon from the plasma plume is deposited, through a series of reactions, onto the single-crystal seed to form diamond. In illustrative embodiments, the single-crystal seed is positioned on a mechanical support. In some chambers, the first position is above the single-crystal seed, and the second position is at a top of the chamber. However, other positions are of the plasma plume are possible.

The method may generate an electric field for biasing the plasma plume. Additionally, or alternatively, the method may generate a magnetic field for biasing the plasma plume. Some embodiments generate a second magnetic field or second electric field to modify the shape of the biased plasma plume.

In accordance with yet another embodiment, a method controls diamond growth. The method provides a single-crystal seed in a growth environment. A gas containing carbon is energized to produce a plasma plume. The method creates steering fields to modulate the deposition characteristics of the plasma plume.

The steering fields are configured to change the shape of the plasma plume. In illustrative embodiments, the method changes the shape of a boundary of the plasma plume facing the seed to have a larger radius of curvature. Additionally, or alternatively, the method may increase the deposition area by changing the shape of the plasma plume to be wider. The steering fields may be generated by using one or more magnetic fields, electric fields, and/or electromagnetic fields.

In accordance with one embodiment of the invention, a position and/or shape of a plasma plume used to grow diamond. The method provides a single-crystal seed in a growth environment. The single-crystal seed is formed from diamond. The method energizes a gas containing carbon to produce a plasma plume that deposits free carbon atoms onto the single-crystal seed. The method also creates steering fields to modulate the carbon atom deposition characteristics of the plasma plume.

In some embodiments, the growth environment is within a chemical vapor deposition chamber. Furthermore, the gas may include methane. The carbon atom deposition characteristics of the plasma plume may be modulated by reshaping the plasma plume and/or changing a density of at least a portion of the plasma plume.

The steering fields may change the shape and/or density of the plasma plume. For example, the steering fields may change the shape of a portion of the plasma plume facing the seed to have a larger radius of curvature (i.e., become more planar). Additionally, or alternatively, the steering fields may increase deposition area by changing the shape of the plasma plume to be wider.

The steering fields may be created by one or more magnetic fields, electric fields, and/or electromagnetic fields. For example, the steering fields may be created by one or more permanent magnets. The magnets may be positioned adjacent to the deposition area. The steering fields may be created using one or more electromagnetic coils. The electromagnetic coil may envelop the deposition area and/or the chamber. The steering fields may also be created via an electrically (voltage) biased ring or plate. In some embodiments, the electromagnetic coils are positioned adjacent to the seed and/or external to the chamber, producing an inductively coupled plasma.

### BRIEF DESCRIPTION OF THE DRAWINGS

The patent or application file contains at least one drawing executed in color. Copies of this patent with color drawing(s) will be provided by the Patent and Trademark Office upon request and payment of necessary fee.

Those skilled in the art should more fully appreciate advantages of various embodiments of the invention from the following “Description of Illustrative Embodiments,” discussed with reference to the drawings summarized immediately below.

FIG. 1 schematically shows a diamond growth environment at the beginning of the diamond growth process in accordance with illustrative embodiments of the invention.

FIG. 2 schematically shows diamond growth in the diamond growth environment in accordance with illustrative embodiments of the invention.

FIGS. 3A-3G schematically show modulation of the plasma plume using different types of electric, magnetic, and/or electromagnetic fields in accordance with illustrative embodiments of the invention.

FIG. 4 shows a process of growing diamonds in accordance with one exemplary embodiment of the invention.

### DESCRIPTION OF ILLUSTRATIVE EMBODIMENTS

Illustrative embodiments adjust a position and/or shape of a plasma plume to improve deposition of diamond using chemical vapor deposition. In particular, illustrative embodiments use microwave plasma chemical vapor deposition. The plasma plume has a shape defined largely by the distribution of ions within the plume. In general, the plume has a predictable shape and position inside of the CVD chamber. Illustrative embodiments use magnetic fields and/or electric fields to advantageously modulate the position and/or shape of the plume.

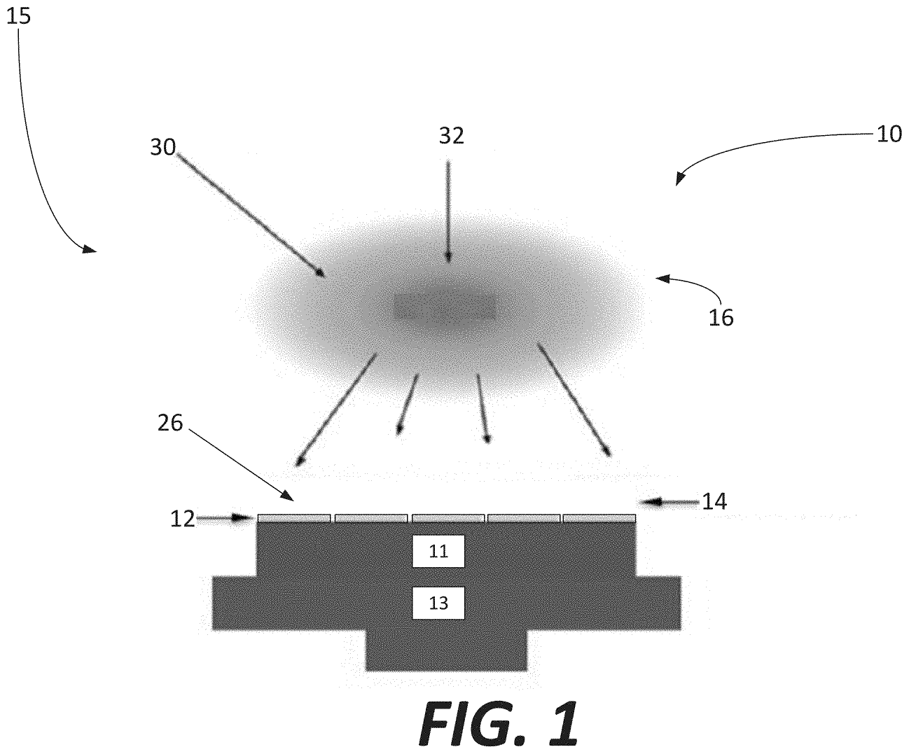

FIG. 1 schematically shows a diamond growth environment 10 in accordance with illustrative embodiments of the invention. In illustrative embodiments, the growth environment 10 is the inside of a chamber 15 used for chemical vapor deposition (CVD). In general, a plasma 16 (also referred to as a plasma plume 16) is produced by ionizing gas 32 (e.g., using microwaves 30 to energize methane). The gas 32 may be injected into the chamber 15, and may include, among other things, various concentrations of hydrogen, methane, argon, nitrogen, and/or oxygen.

Inside the chamber 15 are one or more diamond seeds 12 arranged (e.g., directly) on a refractory metal support 11. The refractory metal support 11 may itself be positioned on a temperature controlled growth stage 13. Alternatively, the diamond seeds 12 may be positioned directly on the growth stage 13.

During the CVD growth process, the chamber 15 is filled with the gas 32 precursors that are formed into the hot plasma 16. As described previously, the plasma 16 may be formed by energizing (e.g., by using microwaves 30) the electrically charged gas 32, such as methane (CH₄). Without wishing to be bound by any particular theory, the inventors believe that when the plasma 16 is energized, the gas 32 atoms break apart, allowing the free carbon atoms to attach to the seed 12 crystals through a series of reactions. Accordingly, diamond 14 (or other crystal 14) growth occurs at a growth interface 26.

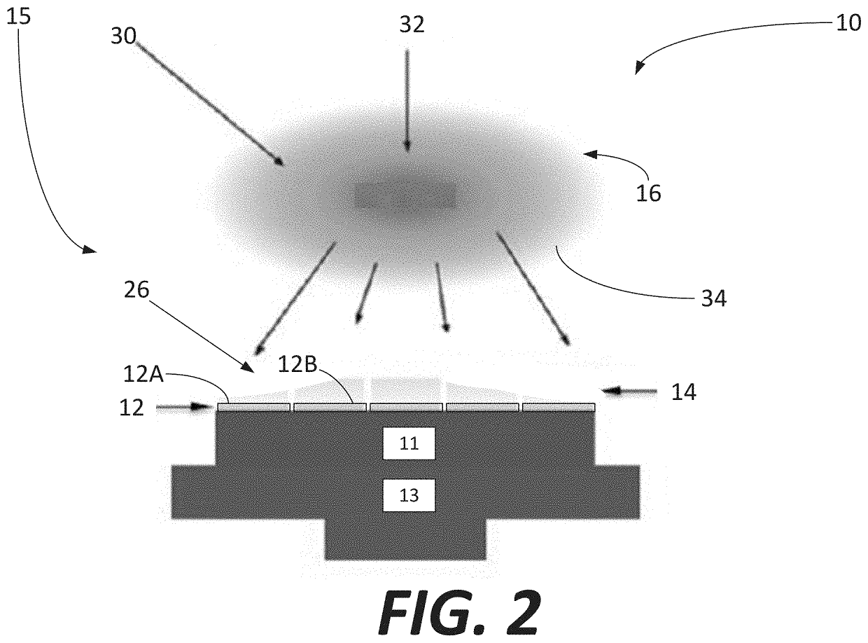

FIG. 2 schematically shows diamond 14 growth in the diamond growth environment 10 in accordance with illustrative embodiments of the invention. The position and/or orientation of the diamond growth interface 26 with respect to the plasma plume 16 impacts the growth of diamonds 14 via CVD. For example, in FIG. 1, the diamond growth interface 26 is the exposed surface of the diamond seed 12. However, in FIG. 2, the diamond growth interface 26 includes a surface defined by new diamond 14 growth.

The plasma plume 16 provides both free radicals and thermal energy for the deposition process. Therefore, the position of the plume 16 with respect to the diamond growth interface 26 (e.g., the diamond seed 12) is a concern for growth mechanisms. It should be understood that while the plume 16 does not have a well-defined boundary, and therefore an exact shape, it is typical to treat the plasma 16 as having a shape for simplicity of discussion. For example, it is possible to visualize the shape of the plasma plume 16 as the area of intense optical emission.

For a typical RF or microwave plasma reactor, the plume 16 tends to be rounded near the growth interface 26, which can make it difficult to maintain uniform growth conditions when growing multiple diamonds 14 simultaneously (e.g., as shown in FIG. 2). The individual diamonds 14 are typically aligned along a single plane (e.g., defined by the seeds 12), while the plasma 16 shape (e.g., the portion of the plume 16 closest to the growth interface 26) is inherently non-planar. For example, the diamond seed 12A is further away from the “boundary” of the plasma plume 16 than the diamond seed 12B. Here, the boundary 34 can be said to include some or all of the plasma plume 16 portion that faces the growth interface 26. This difference in distance from the boundary 34 of the plume 16 causes differences in temperatures and growth conditions of various seeds 12 (e.g., seed 12B towards the middle as compared to the seed 12A towards the edge). Accordingly, as shown in FIG. 2, diamond 14 growth may be non-uniform on seed 12A as compared to the seed 12B.

The results of the inhomogeneous growth conditions that arise from the non-planar shape of the plasma plume 16 include large thermal gradients across the growing diamonds 14. These inhomogeneous growth conditions are caused by thermal gradients across the growing diamonds 14 (i.e., from the plasma 16 itself), as well as varying growth conditions due to the various parts of the growth interface 26 being at different distances from the plasma plume 16 (e.g., the boundary 34).

Illustrative embodiments may modify the plasma 16 shape during growth, including by optimization of procedure and/or injection of inert gaseous species, both of which may alter the kinetics within the plasma plume 16. As discussed below, these techniques can modify the shape of the plume 16. The inventors discovered that active measures may be utilized to modify the shape or position of the plasma 16 in-situ without the need for significant modifications to the process conditions, such as pressure, temperature or gas chemistry.

The modifications to the plume 16 may include, for example, making the plume 16 denser in targeted areas, modifying the boundary 34 of the plume 16 to correspond to the shape of the growth interface 26 (e.g., to normalize distance between boundary 34 and growth interface 26), and/or making the boundary 34 substantially planner. These various modifications may improve growth kinetics and, ultimately, growth rate and final quality of diamond 14 material. As another example, the plume 16 may be broadened, allowing for increased deposition area. Accordingly, grown diamond 14 quantity and quality may be improved.

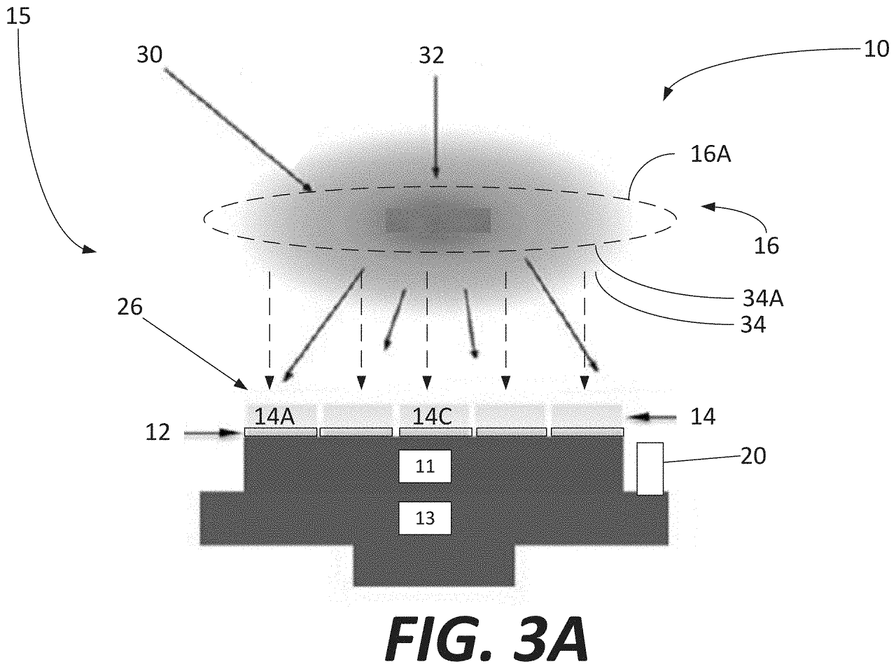

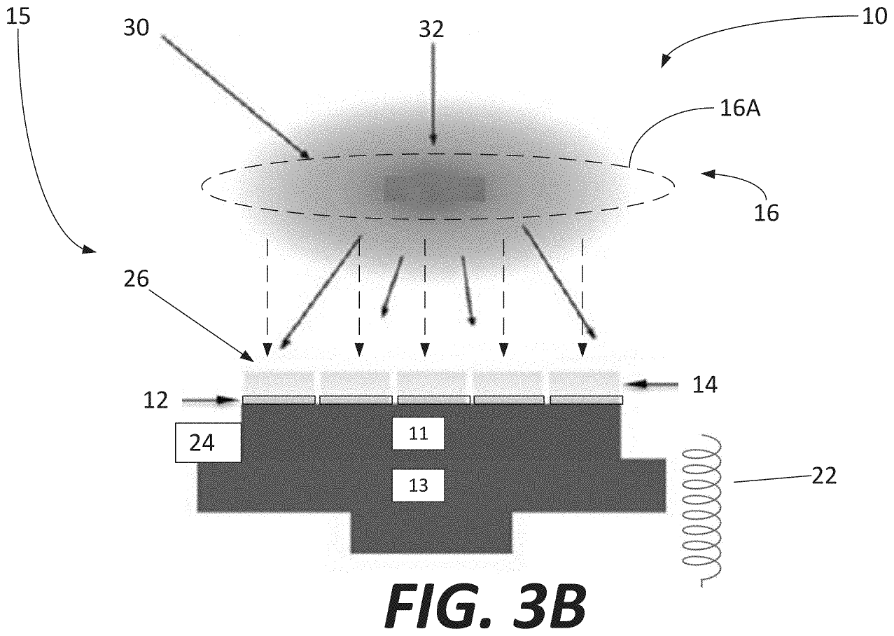

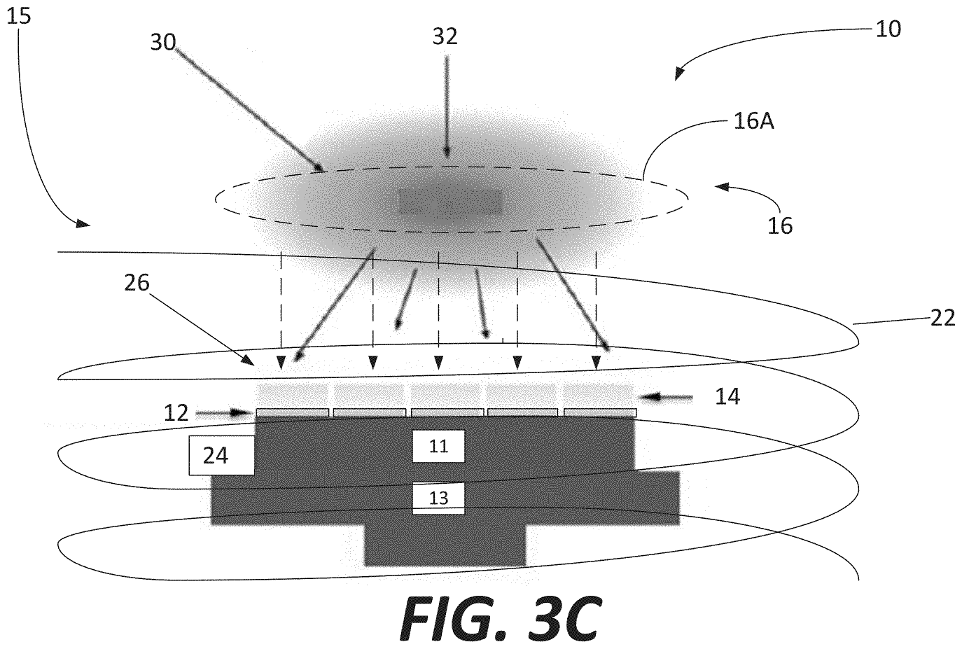

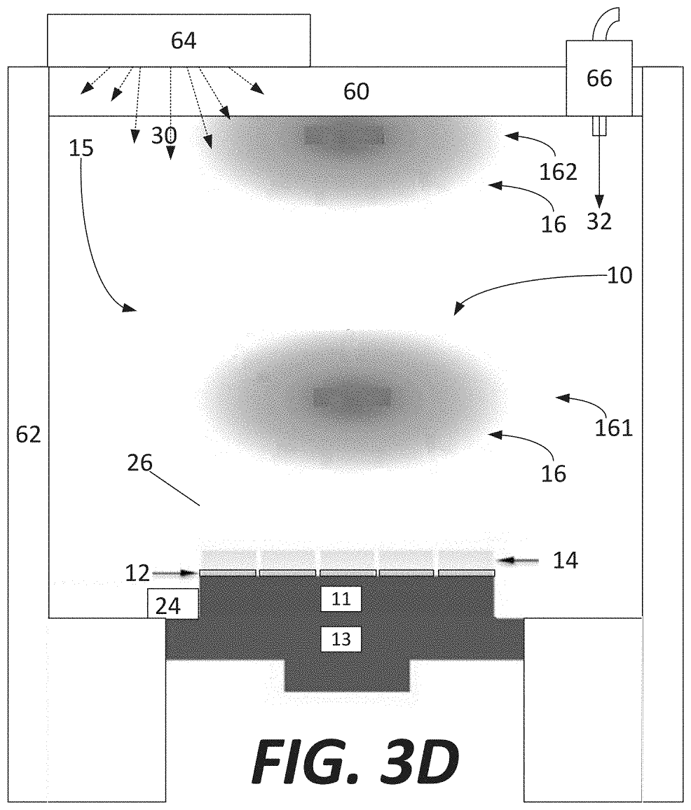

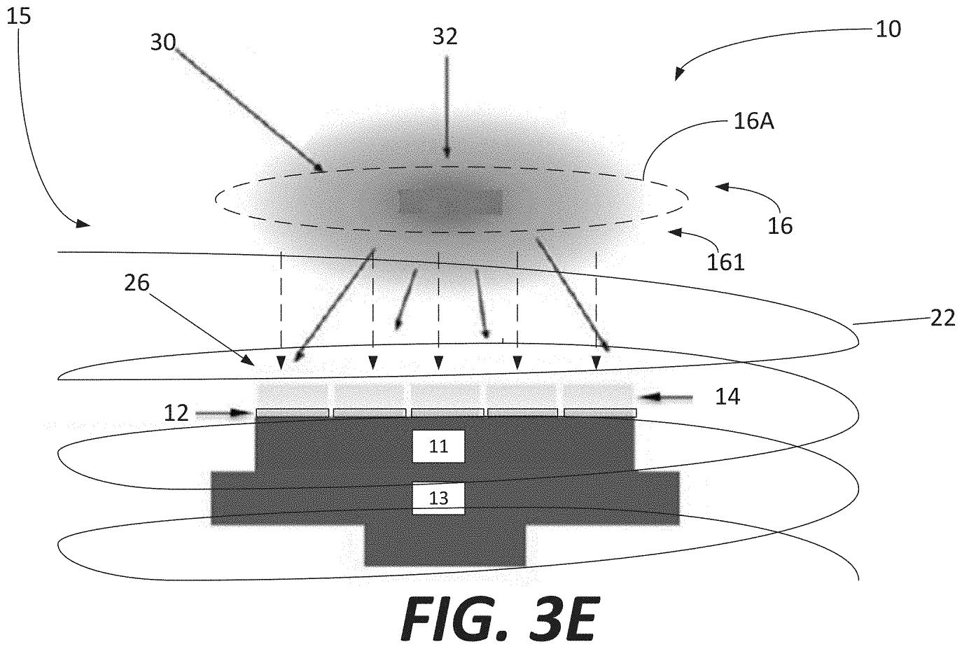

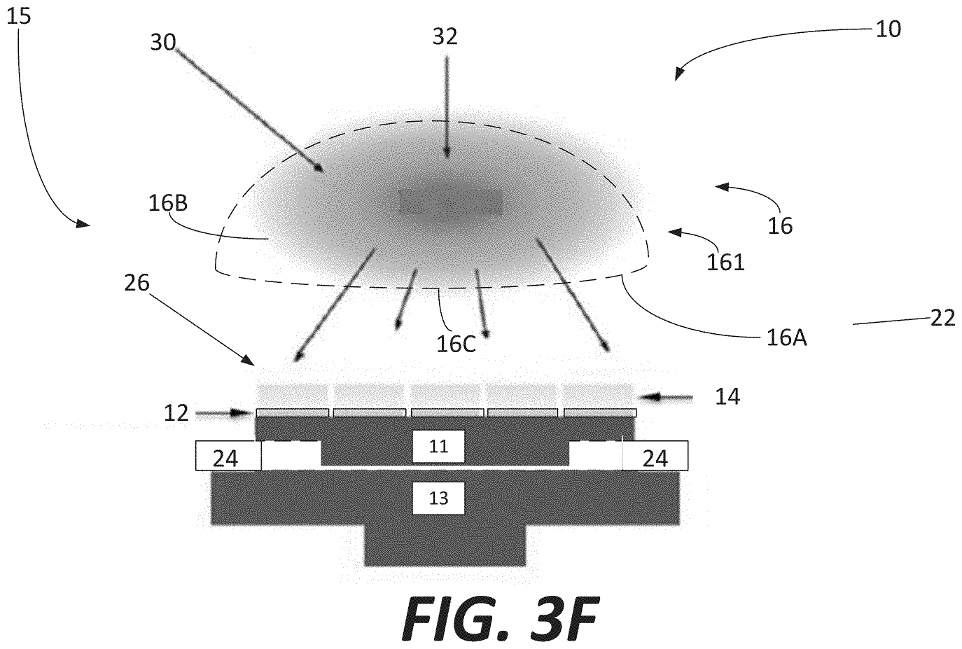

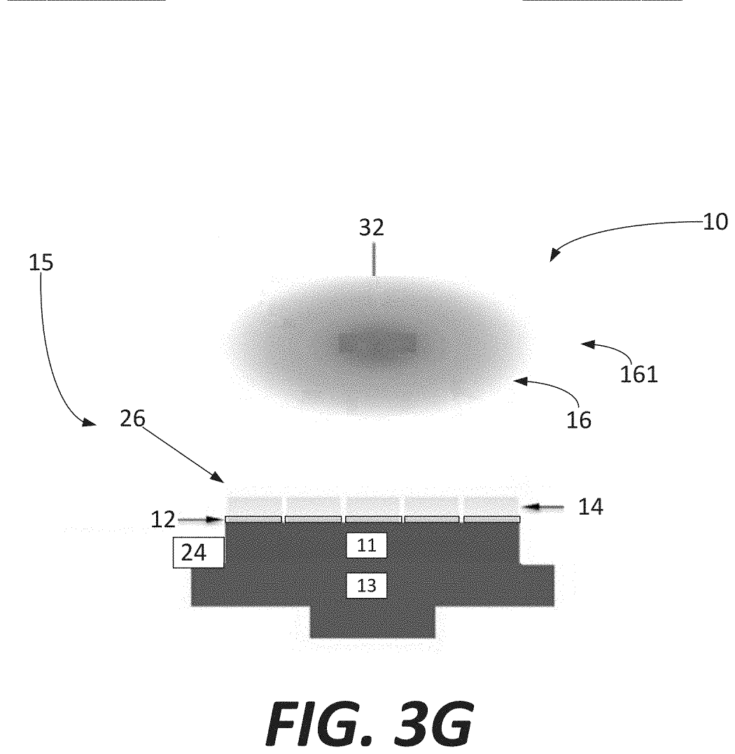

FIGS. 3A-3C schematically show various techniques for reshaping and/or repositioning the plasma plume 16 in accordance with illustrative embodiments of the invention. Specifically, the inventors discovered that the plasma plume 16 can be shaped (also referred to as steered) using electric and/or magnetic fields. These techniques allow for the plasma 16 to be actively reshaped into a reshaped plasma 16A (e.g., including reshaped boundary 34A) by the field (optionally without modifications to process conditions, including pressure and gas chemistry).

By reshaping the plasma plume 16, the growth environment 10 can be made more homogenous, reducing growth variabilities and instabilities. Additionally, the plasma 16 may be made denser in the area of interest, improving growth kinetics and, ultimately, growth rate and final quality of the grown diamond 14 material. In some embodiments, the plume 16 may be broadened such that the reshaped boundary 16A can be considered substantially planar (e.g., the plasma plume 16A has a large radius of curvature facing the diamond growth interface 26). In some embodiments, the plasma 16 may be said to have a radius of curvature at the boundary 34. Illustrative embodiments may shape the plume 16A to increase the radius of curvature, thereby making the boundary 34A less rounded and more planar.

Illustrative embodiments advantageously modify the plasma plume 16 so that the crystals 14A grown near the edge of the growth interface 26 experience substantially the same growth conditions as crystals 14C grown near the center. Without modification of the plume 16, the crystal 14A near the edge sees a different chemistry and temperature from the crystal 14C near the center. In general, the larger the portion of the boundary 34 that is substantially, the more seeds 12 can be positioned within the chamber 15 for simultaneous homogeneous growth. For example, some embodiments may have a plume 16 that provides substantially homogenous growth conditions for a 3×3 arrangement of seeds 12 (e.g., to grow 9 crystals 14). Some embodiments may adjust the shape of the plume 16 such that a 4×4 arrangement of seeds 12 can grow homogeneously (i.e., 16 crystals 14). Accordingly, illustrative embodiments advantageously enable near 2×, or greater than 2×, growth of the number of homogeneous crystals 14 for an otherwise identical growth environment 10. Furthermore, the plume 16 can be flattened (i.e., made substantially planar at the boundary 34 or portions thereof) such that seed crystals 12 may have homogeneous growth conditions in a 5×5 arrangement. Some embodiments enable homogeneous growth of seed 12 arrangements that are greater than 5×5 (e.g., up to 10×10).

To provide homogeneous growth conditions, the shape of the boundary 34 of the plume 16 substantially corresponds to the shape of the growth interface 26. While exact correspondence of shape is desirable, one of skill in the art understands that even minor improvements in the correspondence of the shape of the plume 16 (e.g., the boundary 34) with the shape of the growth interface 26 may provide various advantages described herein.

In general, the seeds 12 are positioned on support 11 and/or stage 13, which are substantially planar. Illustrative embodiments may modify the shape of the plume 16 to be substantially planar (i.e., correspond to the shape of the growth interface 26 which is also substantially planar). It should be understood that while the growth interface 26 may have discontinuities (e.g., between seeds 12), or a minor angular miscut on the seeds 12 and/or diamonds 14, that the growth interface 26 may still be considered to be substantially planar. It is unlikely that the shape of the plume 16 corresponds exactly to the shape of the growth interface 26. However, while exact correspondence between the shape of the plume 16 and the growth interface 26 is theoretically ideal, the inventors have discovered that merely adjusting the shape of the plume 16 to more closely correspond with the shape of the growth interface 26 provides various advantages described herein. Put another way, adjusting the shape of the plume 16 to homogenize diamond 14 growth conditions at the growth interface 26 provides various advantages.

To control the shape of the plume 16 (e.g., the displacement of the ions), illustrative embodiments may use a magnetic field and/or an electric field. The inventors have found that both types of fields are capable of adjusting the shape of the plume 16. This is because the plasma plume 16 is similar to a gas that is electrically conductive, which is highly responsive to electric fields. Because the ions of the plasma 16 are in motion, the shape of the plume 16 is also responsive to magnetic fields. Accordingly, illustrative embodiments may use magnetic and/or electric fields to steer a charged particle, and thereby adjust the shape of the plume 16. In various embodiments, the magnetic and/or electric bias may be applied to the seeds 12 and/or to the plume 16. Furthermore, various portions of the plume 16 may be charged (e.g., the outer edge of the plume 16 may be steered down without steering the center of the plume 16 down).

As shown in FIG. 3A, when the steering field is magnetic in nature, it may include one or more electromagnetic source, such as permanent magnets 20 (e.g., rare earth magnets 20), that are positioned adjacent to the deposition area (e.g., adjacent to the growth interface 26). Alternatively, as shown in FIG. 3B, the field may be produced by one or more electromagnetic source such as electromagnetic coils 22. The magnetic coils 22 may be positioned, for example, external to the chamber 15 to produce an inductively coupled plasma 16A (e.g., wrapped around the chamber 15). Alternatively, or additionally, the magnetic coils 22 may built into the walls of the chamber 15.

FIG. 3C schematically shows an electromagnetic coil 22 surrounding the chamber 15 in accordance with illustrative embodiments of the invention. As described above, the electric and/or magnetic steering fields provide better plasma 16 uniformity. However, illustrative embodiments may also provide better process stability in certain types of reactors. For example, in some reactors, the plasma 16 may have a tendency to move (e.g., between two stable positions).

FIG. 3D schematically shows two different positions 161 and 162 of the plasma plume 16 within the chamber 15 in accordance with illustrative embodiments of the invention. To better assist with illustrating the relative positions 161 and 162 of the plasma 16 in the chamber 15, walls 62 of the chamber 15 are shown. Additionally, a quartz window 60 through which a microwave source 64 emits microwave radiation 30 is also shown. Additionally, a gas injector 66 configured to input gas 32 into the chamber 15 is shown. Although the walls 62, the window 60, the microwave source 64, and the gas injector 66 are not shown in other figures, it should be understood by one of skill in the art that all of these components may be present throughout the other figures. However, these components are emitted from various drawings. Furthermore, it should be understood that the shape, arrangement, and position of the walls 62, window 60, microwave radiation source 64, and gas injector 66 are merely illustrative, and not intended to limit various embodiments.

In preferred embodiments, the chamber 15 is a standing wave chamber 15, which has high reflectivity to microwaves. Thus, the wave bounces within the chamber with relatively low loss. Thus, illustrative embodiments do not have an electrode (as compared to plasma enhanced CVD, which has an RF electrode). In general, the shape of the plasma of a system having an RF electrode is defined by the electrode. In contrast, the shape of the plasma 16 in a microwave chamber 15 is defined by the standing wave. Furthermore, in a microwave chamber 15, the stage on which the samples (e.g., substrates) are positioned is generally not biased.

The inventors have found that microwave fields advantageously provide enhanced diamond growth. While diamond 14 grows in an RF field, the growth rate may be an order of magnitude lower. Disadvantageously, the plasma plume 16 in a microwave field is undesirably small and spherical. In contrast, RF fields typically produce plasma plumes that are advantageously large and relatively flat. Accordingly, illustrative embodiments advantageously adjust the size and/or shape of the plasma 16 using a second field (e.g., electric, magnetic, and/or electromagnetic), thereby improving growth quality and/or the number of diamond 14 grown.

To begin the diamond 14 growth process, the plasma 16 is struck by energizing the gas 32 in the chamber 15 (e.g., by emitting microwave radiation 30 from the microwave source 64 through the quartz window 60). Because microwaves 30 are electromagnetic waves, they produce a first electric field configured to convert the gas 32 into the plasma 16. Thereafter, as known by those of skill in the art, the microwave radiation 30 continues to be emitted during the growth process to maintain the plasma 16. After the plasma 16 is struck, it generally settles in a position 161. However, the position 161 of the plasma 16 may be unstable or metastable, and the plasma 16 may move to a second position 162 (e.g., at the top of the chamber 15 bounded by the quartz window 60). In illustrative embodiments, the first position 161 may be more desirable for diamond 14 growth than the second position 162.

Thus, when the plasma 16 is energized, it may have one or more stable and/or unstable resting positions (e.g., depending on the design of the chamber 15). If both positions are unstable or metastable, then the plasma 16 may move between the first position 161 and the second position 162 over time. The locations of the first position 161 and the second position 162 are a function of the shape of the chamber 15. Thus, some chambers 15 are designed such that they have a single stable position 161 at which the plasma plume 16 rests, and other chambers 15 may have two or more positions 161, 162 that the plasma plume 16 moves between. For example, some chambers 16 may have symmetrical positions (e.g., the first position 161 is at above the platform 11, and the second position 162 is above the first position 161 at the top of the chamber 15). In particular, the inventors have found that cylindrical chambers 15 tend to have the second position 162 at the top of the chamber (e.g., bounded by a quartz window 60 through which the microwave radiation 30 enters the chamber 15).

At any given time, there is a certain probability that the plume 16 is at the first position 161, and a certain probability that the plume 16 is at the second position 162. Furthermore, there may also be decreasing probabilities that the plume 16 may also be at other positions. Illustrative embodiments may use the steering fields described herein to bias the plasma plume 16 towards a single stable position, advantageously increasing the probability that the plasma plume 16 is in the desired position 161.

Illustrative embodiments may activate a second electric field or a first magnetic field (referred to as a positioning field) before, during, and/or after striking the plasma 16. The positioning field electrically and/or magnetically biases the plasma 16 to a particular position 161 or 162. Advantageously, this allows control of the position of the plasma 16 which can ignite in different positions 161 or 162. Furthermore, even if the plasma begins in the desired position 161, it is possible that the plasma 16 can move to the second unstable or metastable position 162 after striking. A person of skill in the art will appreciate that the plasma 16 may grow diamond 14 in a desirable position 161, but can destroy portions of the chamber 15 in an undesired position 162.

Advantageously, illustrative embodiments use positioning fields (e.g., generated by an electrical bias from ring 24 or a magnetic bias from coil 22) to position the plasma plume 16 in a first diamond 14 growth position 161. Accordingly, some embodiments provide a superposition of electric fields and/or magnetic fields (e.g., a first electric field to ignite the plasma and a first magnetic field to position the plasma).

As mentioned above, the size and shape of the chamber 15 impacts the stable positions of the plume 16. However, discussion of the impact of the size and shape of the chamber 15 on the stability and tendency of the plume 16 to move is beyond the scope of this discussion. In general, RF engineers design the chambers 15 to be resonant cavities. Two well-known chamber designs commonly employed in CVD include the clam shell chamber 15 and a cylindrical chamber 15. The inventors have found that the clam shell chamber 15 tends to have a single stable position 161, while the cylindrical chamber 15 tends to cause the plume 16 to move between at least two positions 161 and 162.

FIG. 3E schematically shows the chamber 15 configuration of FIG. 3C with the plume 16 biased in the first position 161. As shown in FIG. 3E, the plasma 16 may be inductively coupled by positioning the electromagnetic coil 22 around the perimeter of the chamber 15. The coil 22 produces a positioning field inside of it that is laminar and parallel to the coil 22. As known by those of skill in the art, the produced electrical field inside of the coil 22 is uniform and points in a single direction. Thus, the coil 22 biases the plume 16 either up or down, depending on the direction of the current. Thus, the coil 22 may be used to bias the plume 16 in its first position 161 in addition to, or as an alternative to, changing the shape of the plume 16.

Furthermore, in illustrative embodiments the metal stage 11 creates a boundary condition for the plasma 16 by creating a repulsive force when the metal stage 11 is electrically charged. Thus, the closer the plasma 16 is pushed towards the stage, the more the electromagnetic force pushes the plasma 16 away. Accordingly, the center of the plasma 16 can be repelled by the stage 11, while the edges of the plasma 16 may get pushed down.

FIG. 3F schematically shows an alternative arrangement for biasing the plume 16 in the first position 161 in accordance with illustrative embodiments. A ring 24 may be positioned around the outside of the diamond 14 growth area and/or growth interface 26. The ring 24 may be electrically biased. In FIG. 3E, the ring 24 is shown at a height lower than the deposition surface. However, in some embodiments, the ring may be at the same height as the deposition surface. The entire ring 24 may be biased. Alternatively, illustrative embodiments may produce local bias points, for example, under each of many individual seeds, in order to compensate for physical variabilities, such as height differentials, between the individual seeds.

By biasing the ring 24, the edges 16B of the plume 16 may be pulled downwards without steering the center 16C downwards. Illustrative embodiments position the ring 24 around the growth so that it is closer to the outer edges 16B of the plume than the center 16C. A variety of dimensions and positions may be used for the ring 24. One of skill in the art knows that field strength is proportional to 1/r². Thus, in the presently described position, the outside edge 16B (which is closer to the ring 24) experiences a greater steering force relative to the center 16C of the plume 16. The plasma 16 is thus steered to flatten out at the edges 16B while having very little impact on the center 16C of the plasma 16 (e.g., as shown in steered plasma 16A).

FIG. 3G shows yet another embodiment for biasing the plume 16 into a desired position and/or shape in accordance with illustrative embodiments of the invention. In FIG. 3G, the stage 11 itself is electrically biased (e.g., by applying a voltage to the stage 11). Similar to the previously discussed embodiments, the steering forces produced by the bias plate are used to steer the plasma into a desired shape and/or position.

In some embodiments, the stage can be biased in targeted locations. For example, the bias can occur at the position of each of the seeds 12. Thus, the seeds 12 can be arranged spaced out from each other around the stage 11, and each seed 12 can be biased independently. Such a biasing configuration provides greater specificity for steering the plasma 16 (e.g., where the plasma 16 should go and where you don't want the plasma 16 to go). This can be particularly advantageous in situations where the seeds 12 don't always grow at the same rate. Thus, if one seed 12 appears to be growing at a faster rate than another seed 12, the seed 12 having reduced growth may draw more plasma 16 towards it. Alternatively, the seed 12 experiencing faster growth may stop or reduce the amount of plasma 16 that is steered towards it. Furthermore, one or more seeds may be biased to push plasma 16 further away, while other seeds 12 attract plasma 16. Thus, it is possible to create very specific plasma 16 reshaping based on the needs of the growth process.

Some embodiments may include temperature sensors configured to detect the temperature at each seed 12. For example, each seed 12 may be on a discrete pad that may have a unique voltage applied thereto. Each pad may also have a discrete temperature sensor. However, due to the process conditions, the pads likely would not have sensors. Instead, illustrative embodiments may measure the temperature optically, such as with a pyrometer or IR camera. In general, the closer the plasma 16 is to a particular part of the growth interface 26, the hotter the temperature is at that location. Thus, temperature feedback can be used to automatically adjust the amount of plasma 16 that is steered to a particular location. For example, if one seed 12 is hotter than another, the temperature of the hotter seed 12 can trigger a microcontroller to change the biasing voltage and reduce the steering of plasma towards that seed 12. Although a simple example for one seed is described here, it should be apparent that this temperature feedback may be used simultaneously for a plurality of seeds.

Additionally, or alternatively, optical feedback may be used to adjust the steering fields. For example, a camera can image the plasma 16 and communicate with a controller that maps out the shape of plume 16 as a function of the intensity of the light. The intensity of the light can be used to adjust the height of various parts of the plasma plume 16.

Although feedback is discussed with reference to FIG. 3F, it should be apparent to one skill in the art that the feedback mechanisms discussed herein may be employed with any of the various electromagnetic biasing configurations disclosed herein, and variations thereof.

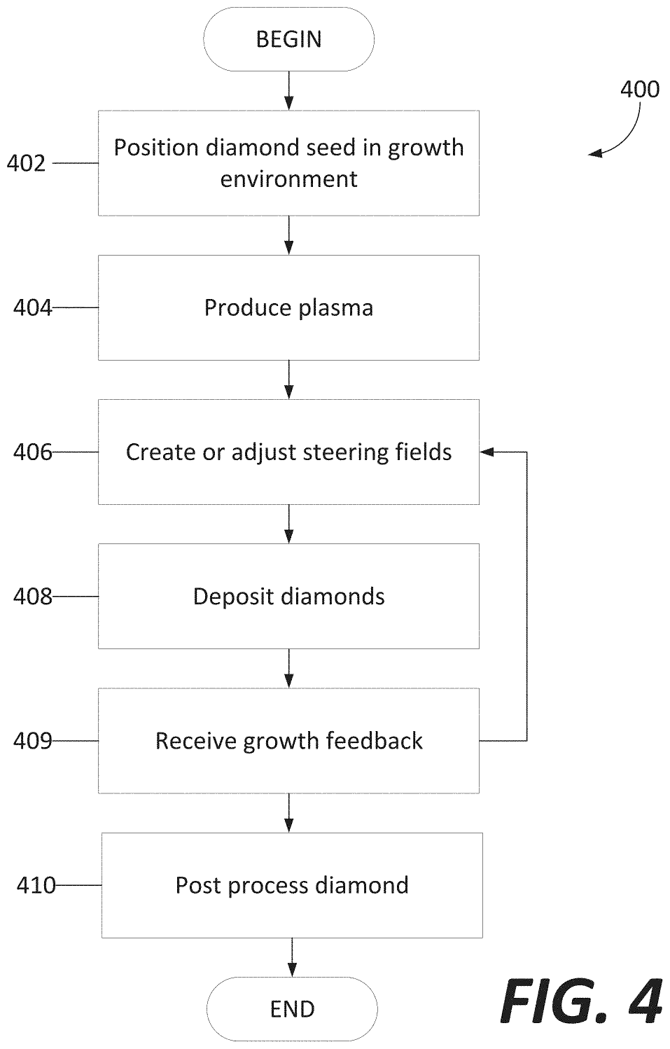

FIG. 4 shows a process 400 of growing one or more diamonds in accordance with one embodiment of the invention. It should be noted that this method is substantially simplified from a longer process that may normally be in used. Accordingly, the method of FIG. 4 may have many other steps that those skilled in the art likely would use. In addition, some of the steps are optional (e.g., step 410) and/or may be performed in a different order than that shown (e.g., step 406 may begin before step 404), or at the same time. Those skilled in the art therefore can modify the process as appropriate.

Moreover, as noted above and below, many of the materials and structures noted are but one of a wide variety of different materials and structures that may be used. Those skilled in the art can select the appropriate materials and structures depending upon the application and other constraints. Accordingly, discussion of specific materials and structures is not intended to limit all embodiments.

The process 400 may be executed inside a furnace, reactor, or other device (not shown) having a chamber 15 with carefully controlled environmental conditions, such as prescribed pressures, temperatures, and environmental gasses. As an example, the process 400 may be carried out using the CVD method.

The process begins at step 402, which positions the diamond seed 12 in the growth environment 10 (e.g., inside the vacuum sealed CVD chamber 15 as shown in FIG. 1). Specifically, the diamond seed 12 may be positioned on a refractory metal support 11, which itself may be on a temperature-controlled growth stage 13. Although illustrative embodiments refer to diamond 14 growth, among other things, the seed 12 may be formed from, for example, magnesium oxide, iridium, silicon, yttrium-stabilized zirconium, titanium, silicon carbide, diamond, or combinations thereof. Those skilled in the art may select yet a different material for the seed 12. Preferably, the seed 12 has a single crystal/monocrystalline structure. In illustrative embodiments where the seed 12 is formed from diamond, the seed 12 growth surface may have a (100) crystal orientation with a miscut/misorientation in the range of about ±5 degrees.

In various embodiments, one or more diamond seeds 12 may be positioned within the chamber 15. Furthermore, although the diamond seeds 12 are shown as being aligned on a planar surface, in some embodiments, the diamond seeds 12 may be positioned differently (e.g., to match the expected “shape” of the plume 16).

The process then proceeds to step 404, which produces the plasma 16 (also referred to as striking the plasma 16). As described previously, the growth environment 10 includes the gas 32, such as methane (CH₄), which becomes a plasma 16 when it is energized 30 (e.g., by microwaves). The gas 32 may be injected into the chamber 15. In some embodiments, the gas 32 may include hydrogen, methane, argon, nitrogen, and/or oxygen. The plasma 16 provides a source of carbon that is deposited onto the seeds 12 (e.g., the diamond seed 12). Accordingly, the diamond 14 growth process begins.

The process then proceeds to step 406, which creates steering fields configured to reshape the plume 16 to guide the deposition of material from the plume 16 (e.g., a carbon containing ion) and/or to bias the plume 16 towards a certain position. To that end, illustrative embodiments may include magnets 20 (e.g., as shown in FIG. 3A) or electromagnetic coils 22 (e.g., as shown in FIG. 3B). While FIG. 3B shows that the coil 22 envelops and/or surrounds the deposition area, it should be understood that this is merely for illustrative purposes and not intended to limit various embodiments. Indeed, in some embodiments, the coil 22 envelops and/or surrounds the deposition area. In some other embodiments, for example, the coil 22 may envelop the entire chamber 15 (e.g., the coil 22 may be positioned along the perimeter of the chamber 15).

In the case that the steering field is electric, the result is a superposition of two fields, i.e., an alternating microwave field combined with an RF or DC field. The field may be produced adjacent to the deposition area, via an electrically biased ring or plate 24 having a given voltage. Alternatively, the bias may be applied to a ring 24 that encompasses the deposition area and is positioned at a height similar to, or less than the height of the deposition surface (e.g., platen). It may also be desirable to produce local bias points, for example, under each of many individual seeds, in order to compensate for physical variabilities, such as height differentials, between the individual seeds. It may be further advantageous to control the field strength, either locally or through shaping the field, though an automated process, such as is done with PID controls. Accordingly, the field strength may be modulated via an independent variable such as growth rate or temperature.

As described previously, the steering fields may be used to change the shape of the plasma plume 16 (e.g., see reshaped plasma 16A in FIGS. 3A-3B). For example, the plasma plume 16 may be broadened to better reach more seeds 12. Additionally, or alternatively, the shape of the plasma plume 16 may be adjusted to provide more homogenous growth characteristics. Additionally, or alternatively, the steering fields may be used to change the position of the plasma plume 16.

The process then proceeds to step 408, which deposits diamond 14. Although shown as occurring after step 406, it should be understood that the diamond 14 deposition process may occur as the plasma plume 16 is produced. However, the density and positioning of the deposited diamond 14 may be changed when the steering fields are created. In some embodiments, such as when permanent magnets are utilized, the fields may always be present, even when the reactor is not in use. Accordingly, the ‘deposition profile’ of the plume 16 is changed.

At step 409, the process receives diamond 14 growth feedback. The feedback may be relevant to a temperature of the one or more seeds 12. The feedback may also be from a visual monitoring/inspection system (e.g., a camera) that views the plasma plume 16 from the side, and determines a distance of the plume 16 to particular seeds 12. Additionally, or alternatively, an optical and/or laser measuring system may measure the height of the grown diamond 14. The various types of feedback described herein are illustrative, and not intended to limit various embodiments of the invention.

The process may return to step 406, which adjusts the steering fields on the basis of the feedback received in step 409. For example, if a particular seed 12 has a higher temperature than other seeds 12, then the system can reduce the steering forces that attract the plasma plume 16 towards that seed 12. As another example, if a particular diamond 14 has not grown as quickly as other diamonds 14, the height of the shorter diamond 14 can be used as feedback to attract the plasma plume closer to that diamond (e.g., either by pulling the plume 16 down closer to the diamond 14 and/or widening the plume). One of skill in the art can envision various ways that the feedback could be use to adjust the steering fields. In illustrative embodiments, the steering fields are adjusted to make the growth rate of the various diamonds 14 grown more uniform.

The process concludes at step 410, which post processes the diamond 14. For example, the process may polish or anneal one or both sides of the resulting diamonds 14 depending on their ultimate application. For example, one side of the diamond 14 may be polished, and/or the grown diamond 14 may be doped for some downstream application. Other post-process may cut the grown bulk diamond 14 into wafers of prescribed sizes or shapes.

It should be understood that while the above discussion refers to a CVD process, illustrative embodiments may also work with a Physical Vapor Deposition (PVD) process. For example, pulsed laser deposition (PLD) is a PVD technique where a high-power pulsed laser beam is focused inside a vacuum chamber to strike a target of the material that is to be deposited. This material is vaporized from the target in a plasma plume, which deposits it as a thin film on a substrate (such as a silicon wafer facing the target). Accordingly, illustrative embodiments may apply to a variety of deposition types that produce a plasma plume.

The embodiments of the invention described above are intended to be merely exemplary; numerous variations and modifications will be apparent to those skilled in the art. Such variations and modifications are intended to be within the scope of various embodiments.

1. A system for growing diamonds, the system comprising:
a chemical vapor deposition reactor, the reactor including a microwave chamber;
a single-crystal seed configured to be positioned in the chamber;
a precursor gas;
a microwave source configured to energize the precursor gas to produce a plasma plume;
an electromagnetic source configured to generate a steering field to adjust a position of the plasma plume in the chamber and/or to adjust a shape of the plasma plume.

2. The system as defined by claim 1, wherein the microwave source produces a first electric field that energizes the gas, the first electric field and the steering field being at least partially superposed.

3. The system as defined by claim 1, further comprising a mechanical support on which the single-crystal seed is positioned.

4. The system as defined by claim 1, further comprising a plurality of single-crystal seeds, the single-crystal seeds formed from diamond.

5. The system as defined by claim 1, wherein the electrically charged gas includes methane and hydrogen.

6. The system as defined by claim 1, wherein the energy source emits microwave radiation.

7. The system as defined by claim 1, wherein the electromagnetic source includes a magnetic coil, and/or an electrically charged ring.

8. The system as defined by claim 3, wherein the electromagnetic source includes an electrically biased mechanical support.

9. The system as defined by claim 1, further comprising a deposition feedback system.

10. The system as defined by claim 9, wherein the deposition feedback system determines a temperature of one or more seeds, measures a dimension of one or more grown diamonds, and/or determines a shape of a plasma plume.

11. A method of growing diamonds, the method comprising:
generating a plasma plume in a chamber, the chamber configured so that the plasma plume is unstable or metastable, such that the plasma plume moves between a first position and a second position; and
biasing the plasma plume towards the first position.

12. The method as defined by claim 11, further comprising generating an electric field for biasing the plasma plume.

13. The method as defined by claim 11, further comprising generating a magnetic field for biasing the plasma plume.

14. The method as defined by claim 11, further comprising:
providing a single-crystal seed in the chamber;
depositing carbon from the plasma plume onto the single-crystal seed to form diamond.

15. The method as defined by claim 14, wherein the single-crystal seed is on a mechanical support.

16. The method as defined by claim 15, wherein the first position is above the single-crystal seed, and the second position is at a top of the chamber.

17. The method as defined by claim 11, wherein the chamber is a cylindrical chamber.

18. The method as defined by claim 11, further comprising creating a second magnetic field or electric field to modify the shape of the biased plasma plume.

19. A method of controlling diamond growth, the method comprising:
providing a single-crystal seed in a growth environment;
energizing a gas containing carbon to produce a plasma plume; and
creating steering fields to modulate the carbon atom deposition characteristics of the plasma plume.

20. The method as defined by claim 19, wherein the growth environment is within a chemical vapor deposition chamber.

21. The method as defined by claim 19, wherein the gas is methane.

22. The method as defined by claim 19, wherein the steering fields change the shape of the plasma plume.

23. The method as defined by claim 22, further comprising changing the shape of a boundary of the plasma plume facing the seed to have a larger radius of curvature.

24. The method as defined by claim 22, further comprising increasing deposition area by changing the shape of the plasma plume to be wider.

25. The method as defined by claim 19, wherein the steering fields are created using one or more magnetic fields, electric fields, and/or electromagnetic fields.
